(19) United States
(12) Patent Application Publication
(10) Pub. No.: US 2017/0098678 A1
(43) Pub. Date: Apr. 6, 2017

(54) CHIP SCALE SENSING CHIP PACKAGE AND A MANUFACTURING METHOD THEREOF

(71) Applicant: XINTEC INC., Taoyuan City (TW)

(72) Inventors: Chaung-Lin LAI, Taoyuan City (TW); Wei-Ming CHIEN, Taoyuan City (TW)

(21) Appl. No.: 15/280,959

(22) Filed: Sep. 29, 2016

Related U.S. Application Data
(60) Provisional application No. 62/236,129, filed on Oct. 1, 2015.

(51) Int. Cl. H01L 27/146

(52) U.S. Cl. CPC H01L 27/14636; H01L 27/1462; H01L 27/14687; H01L 27/14685

(57) ABSTRACT

This present invention provides a chip scale sensing chip package, comprising: a sensing chip with a first top surface and a first bottom surface opposite to each other, wherein the first top surface has a first insulating layer formed thereon, and the sensing chip comprises a sensing device adjacent to the first top surface and a plurality of conductive pads formed within the first insulating and adjacent to the sensing device, and a wiring layer formed on the first bottom surface to respectively connect to each of the conductive pads; and a dam formed on the first insulating layer adjacent to the sensing device.

This application claims the benefit of U.S. provisional application No. 62/236,129, filed on Oct. 1, 2015, and the entirety of which is incorporated by reference herein.

### BACKGROUND OF THE INVENTION

Field of the Invention

The present invention relates to a sensing chip package and in particular relates to a proximity sensing chip package and a manufacturing method thereof.

Description of the Related Art

A conventional chip package having sensing function is easily contaminated or damaged during the manufacturing processes which results in decreasing both the yield and liability of conventional chip package having sensing functions. In order to meet the tendency of size-miniaturization of electronic components, it is an import subject to minimize the thickness of a substrate for carrying a semiconductor chip to be packaged. The circuit is formed on a thin chip layer during the manufacturing process of a package substrate. However, if a thin substrate for carrying a semiconductor chip to be packaged is utilized, the yield will be reduced owing to the thin substrate is bended or damaged during the package process.

In addition, in order to provide an image sensing chip package with a better image quality, the sensing device of the image sensing chip package must be spaced with the cap layer by a proper distance. Therefore, a dam consisted of a photoresist pattern, a silicon nitride and so on is sandwiched between the image sensing chip and the cap for package to maintain a proper distance. However, the thickness of a dam consisted of a photoresist pattern is 40 μm at most owing to the limitation of photolithography, and the light passing through the dusts falling on the cap layer will be twisted or interfered and results in ghost image or light reflection. Also, the photoresist pattern is photosensitive and unstable, which will reduce the optical performance and stability of the image sensing chip package.

The thermal expansion coefficients (CTE) of glass, silicon nitride and the photoresist pattern are about 3.25, 2.3 and 55, wherein the cap layer of the sensing chip package usually consisted of glass which will result in bending owing to the thermal expansion and contraction effect when the cap layer and the dam are consisted of materials with different thermal expansion coefficients.

In order to resolve above-mentioned problems, this present invention provides a novel chip scale sensing chip package and a manufacturing thereof by applying a cap layer and a dam consisted of the same materials to improve abovementioned disadvantages of bending owing to the thermal expansion and contraction effect when the cap layer and the dam are consisted of materials with different thermal expansion coefficients.

In order to resolve above-mentioned problems, this invention provides a novel chip scale sensing chip package and a manufacturing method thereof, which is characterized by applying a cap layer and a dam consisted of the same materials to avoid abovementioned bending.

### SUMMARY OF THE INVENTION

A feature of this invention provides a chip scale sensing chip package, comprising: a sensing chip, comprising: a sensing device substrate having a first top surface and a first bottom surface opposite to each other; a first insulating layer formed on the first top surface; a sensing device formed within the sensing device substrate and adjacent to the first top surface; and a plurality of conductive pads formed within the sensing device substrate and adjacent to the sensing device; a wiring layer formed on the first bottom surface and connected to each of the conductive pads; and a dam, formed on the first insulating layer adjacent to the sensing device.

Another feature of this invention provides a chip scale sensing chip package as mentioned above, wherein the wiring layer comprises: a plurality of first through holes passing through the first top surface and the first bottom surface of the sensing chip, and each of the first through holes has a bottom wall exposing one of the conductive pads and a sidewall surrounding the bottom wall; a second insulating layer formed on the first bottom surface and overlaid the sidewall and the bottom wall of each first through hole; a plurality of second through hole passing through the second insulating layer on each of the first through holes and exposing one of the conductive pads corresponding thereof; a re-distribution layer formed on the second insulating layer and electrically connected to each of the conductive pads via each of the second through holes; a passivation layer formed on the re-distribution layer and having a plurality of third through holes exposing the re-distribution layer; and a plurality conductive structures respectively formed in each of the third through holes to respectively interconnected to re-distribution layer.

Another feature of this invention provides a chip scale sensing chip package as mentioned above, wherein the wiring layer comprises: a plurality of fifth through holes passing through the first top surface and the first bottom surface of the sensing chip, wherein each fifth through hole has a sidewall exposing the edge of each conductive pad; a second insulating layer formed on the first bottom surface and overlaid the sidewall of each fifth through hole; a re-distribution layer formed on the second insulating layer and electrically connected to the edge of each conductive pad; a passivation layer formed on the re-distribution layer and having a plurality of sixth through holes exposing the re-distribution layer; and a plurality conductive structures respectively formed in each of the sixth through holes to respectively interconnected to re-distribution layer.

Another feature of this invention provides a chip scale sensing chip package as mentioned above, further comprising a cap layer formed above the sensing device and joined with the dam.

Another feature of this invention provides a chip scale sensing chip package as mentioned above, wherein the dam and the cap layer are consisted of materials with the same thermal expansion coefficients.

Another feature of this invention provides a chip scale sensing chip package as mentioned above, further comprising a first adhesive layer sandwiched between the cap layer and the dam.

Another feature of this invention provides a chip scale sensing chip package as mentioned above, further comprising a second adhesive layer sandwiched between the dam and the first insulating layer.

Another feature of this invention provides a chip scale sensing chip package as mentioned above, wherein the dam has a thickness of 20˜60 μm.

Another feature of this invention provides a chip scale sensing chip package as mentioned above, wherein the dam has a thickness of 400˜600 μm.

Another feature of this invention provides a method of manufacturing a chip scale sensing chip package, comprising the steps of: providing a sensing device substrate having a first top surface with a first insulating layer formed thereon and a first bottom surface, wherein the sensing device substrate has a plurality of sensing chip regions spaced by a plurality of scribing channels, and each sensing chip comprises a sensing device formed in the sensing device substrate adjacent to the first top surface and a plurality of conductive pads formed within the sensing device substrate and adjacent to the sensing device; providing a cap layer having a second top surface with a plurality of dams formed thereon and a second bottom surface opposite to each other, wherein each dam corresponds to each sensing chip region, and the cap layer and the dam have the same thermal expansion coefficients; attaching the cap layer to the first top surface of the sensing device substrate to sandwich the dam between the cap layer and the sensing device substrate; forming a wiring layer on the first bottom surface to respectively interconnect each of the conductive pads; forming a passivation layer on the wiring layer; and scribing the sensing device substrate along the scribing channels to generate a plurality of chip scale sensing chip packages.

Another feature of this invention provides a method of manufacturing a chip scale sensing chip package as mentioned above, wherein the sensing device substrate, the dam and the cap layer are consisted of materials with the same thermal expansion coefficients.

Another feature of this invention provides a method of manufacturing a chip scale sensing chip package as mentioned above, wherein the method of manufacturing the dam comprises the steps of: providing a substrate; formed a first adhesive layer on the substrate or on the cap layer; joining the substrate and the cap layer to form a stacking layer by sandwiching the first adhesive layer therebetween; patterning the substrate to form dams on the cap layer, wherein the first adhesive layer is sandwiched between the dam and the substrate.

Another feature of this invention provides a method of manufacturing a chip scale sensing chip package as mentioned above, further comprising a step of peeling off the cap layer from each of the chip scale sensing chip package.

Another feature of this invention provides a method of manufacturing a chip scale sensing chip package as mentioned above, whereby the method of manufacturing the wiring layer comprises the steps of: thinning the first bottom surface of the sensing device substrate; forming a plurality of first through holes on the thinned first bottom surface, wherein each of the first through holes exposes one of the conductive pads; forming a second insulating layer overlaid the thinned first bottom surface, the first through holes and the exposed conductive pads; removing part of the second insulating layer on the bottom of each first through hole to form a plurality of second through holes exposing the conductive pads; forming a re-distribution layer on the second insulating layer and electrically connecting to each conductive pad through each second through hole; forming a passivation layer on the re-distribution layer, whereby the passivation layer has a plurality of third through holes exposing the re-distribution layer; and forming a conductive structure in each of the third through holes and electrically connecting to the re-distribution layer.

Another feature of this invention provides a method of manufacturing a chip scale sensing chip package as mentioned above, wherein the cross-sectional area of each first through hole decreases with the distance from the first bottom surface.

Another feature of this invention provides a method of manufacturing a chip scale sensing chip package as mentioned above, whereby the method of manufacturing the wiring layer comprises the steps of: thinning the first bottom surface of the sensing device substrate; forming a plurality of fourth through holes on the thinned first bottom surface, wherein each of the fourth through holes exposes one of the conductive pads; forming a second insulating layer overlaid the thinned first bottom surface, the fourth through holes and the exposed conductive pads; removing part of the second insulating layer, part of the conductive pads and part of the first insulating layer in each of the fourth through hole by notching to form a plurality of fifth through holes, wherein each fifth through hole has a sidewall exposes one of the conductive pads; forming a re-distribution layer on the second insulating layer and electrically connecting to each conductive pad through each fifth through hole; forming a passivation layer on the re-distribution layer, whereby the passivation layer has a plurality of sixth through holes exposing the re-distribution layer; and forming a conductive structure in each of the sixth through holes and electrically connecting to the re-distribution layer.

Another feature of this invention provides a method of manufacturing a chip scale sensing chip package as mentioned above, wherein the cross-sectional area of each fourth through hole decreases with the distance from the first bottom surface.

Another feature of this invention provides a method of manufacturing a chip scale sensing chip package as mentioned above, further comprising a second adhesive layer sandwiched between the dam and the first insulating layer.

Another feature of this invention provides a method of manufacturing a chip scale sensing chip package as mentioned above, wherein the dam has a thickness of 20∞60 μm.

Another feature of this invention provides a method of manufacturing a chip scale sensing chip package as mentioned above, wherein the dam has a thickness of 400˜600 μm.

### BRIEF DESCRIPTION OF THE DRAWINGS

FIGS. 1A˜1K are cross-sectional views of a method of manufacturing a chip scale sensing chip package according to the exemplary embodiment 1 of this present invention.

FIGS. 1I′˜1L′ are cross-sectional views of a method of manufacturing a chip scale sensing chip package according to the exemplary embodiment 2 of this present invention.

FIG. 2 is a cross-sectional view of a chip scale sensing chip package according to the exemplary embodiment 3 of this present invention.

FIG. 3 is a cross-sectional view of a chip scale sensing chip package according to the exemplary embodiment 3 of this present invention.

### DETAILED DESCRIPTION OF THE INVENTION

The making and using of the embodiments of the present disclosure are discussed in detail below. However, it should be noted that the embodiments provide many applicable inventive concepts that can be embodied in a variety of specific methods. The specific exemplary embodiments discussed are merely illustrative of specific methods to make and use the embodiments, and do not limit the scope of the disclosure.

### Exemplary Embodiment 1

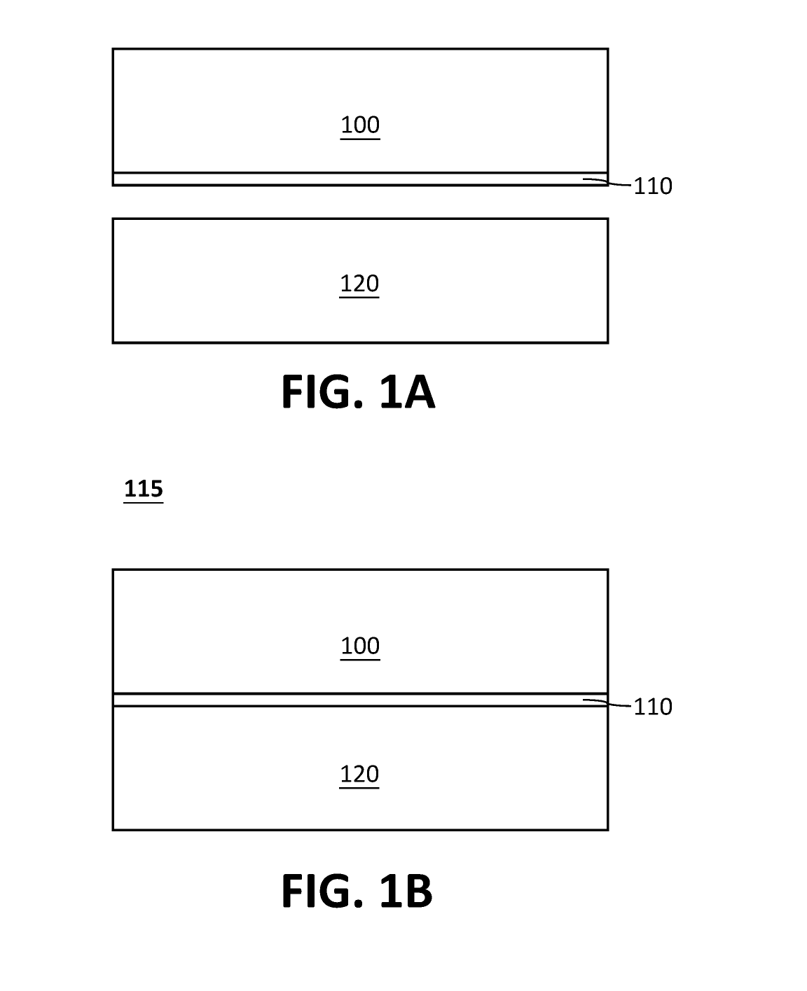

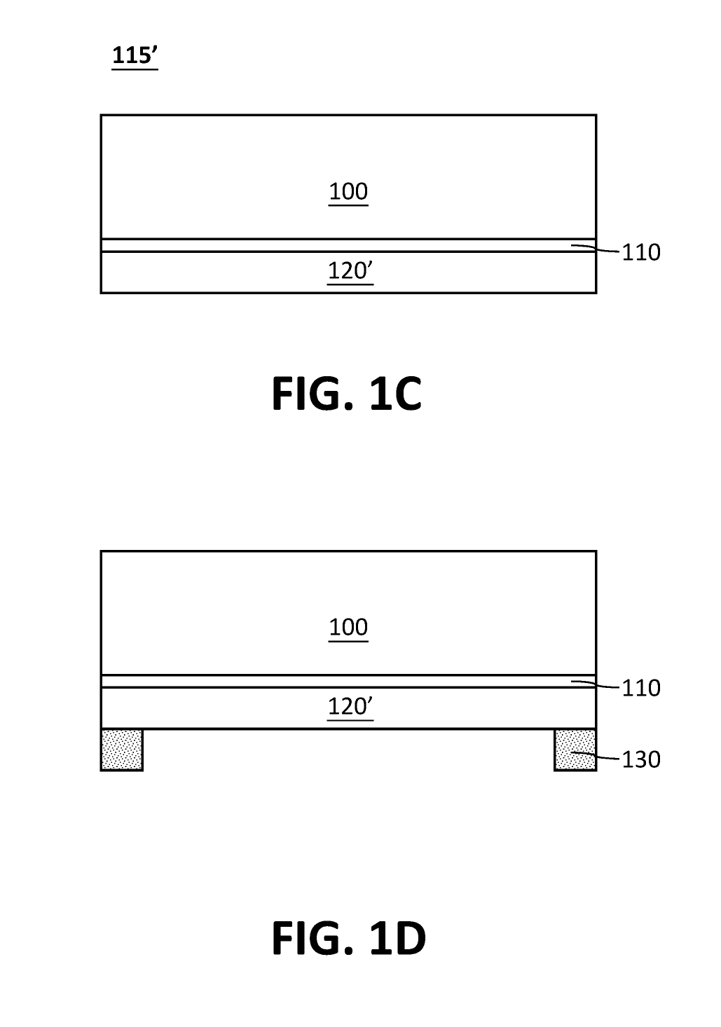

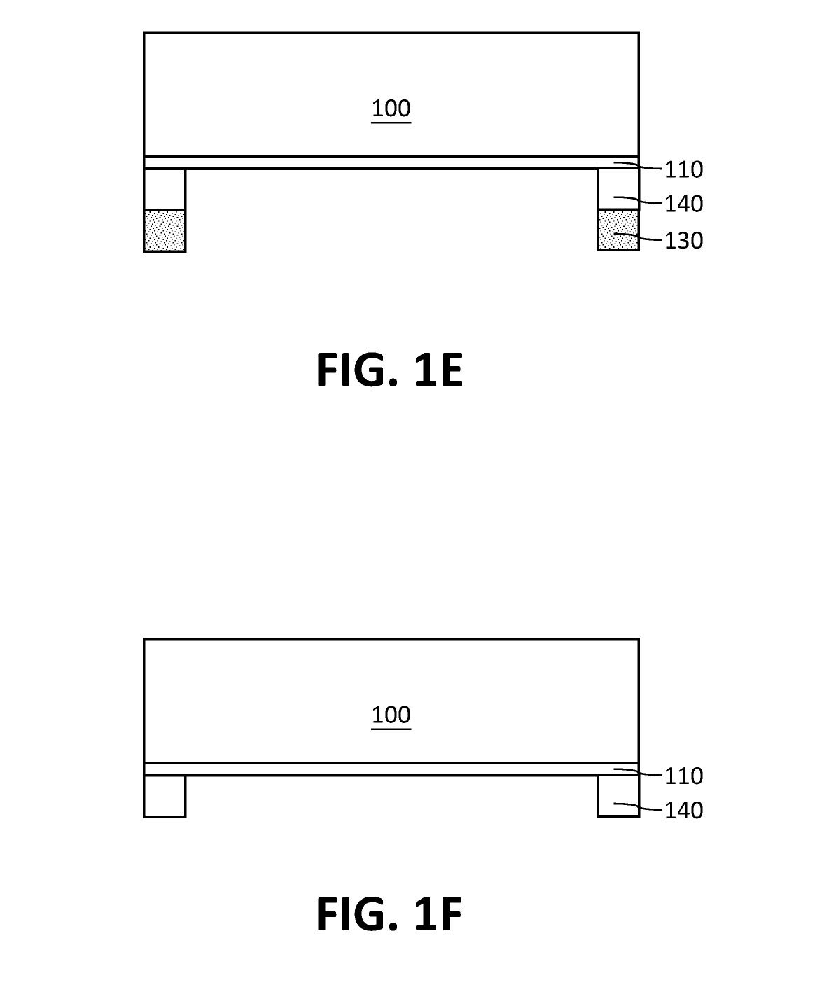

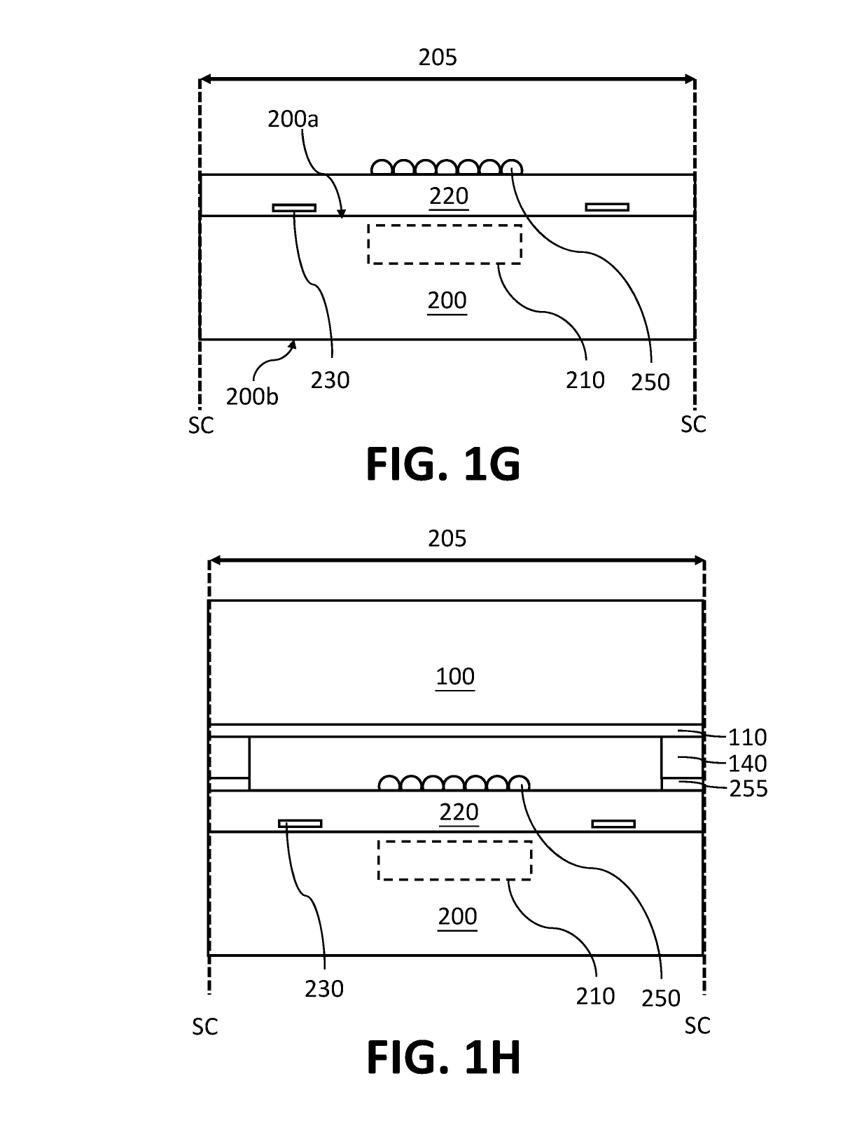

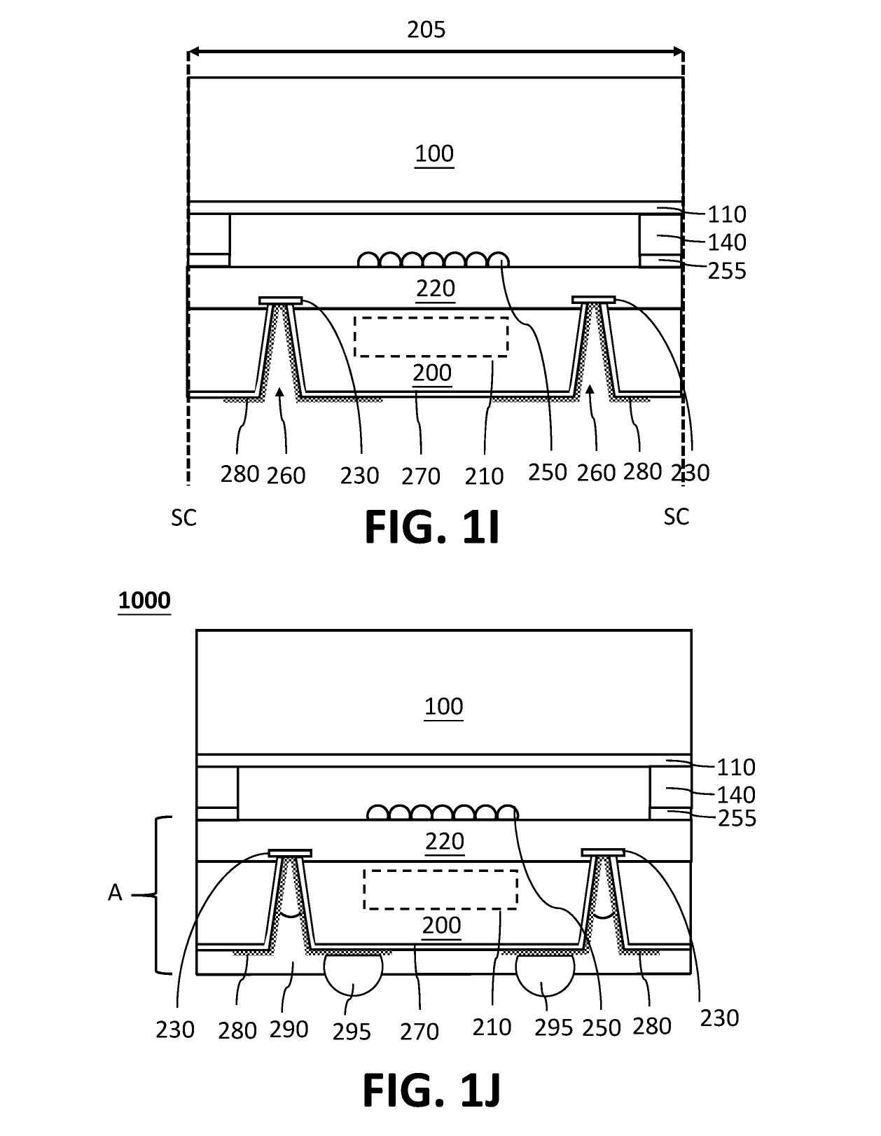

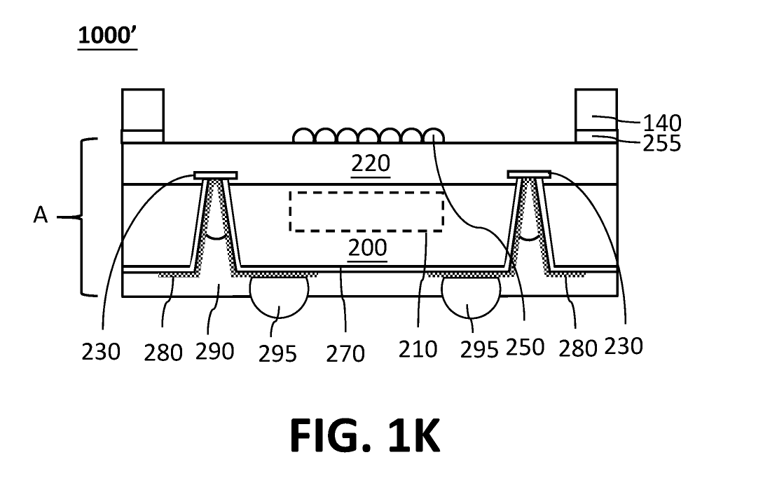

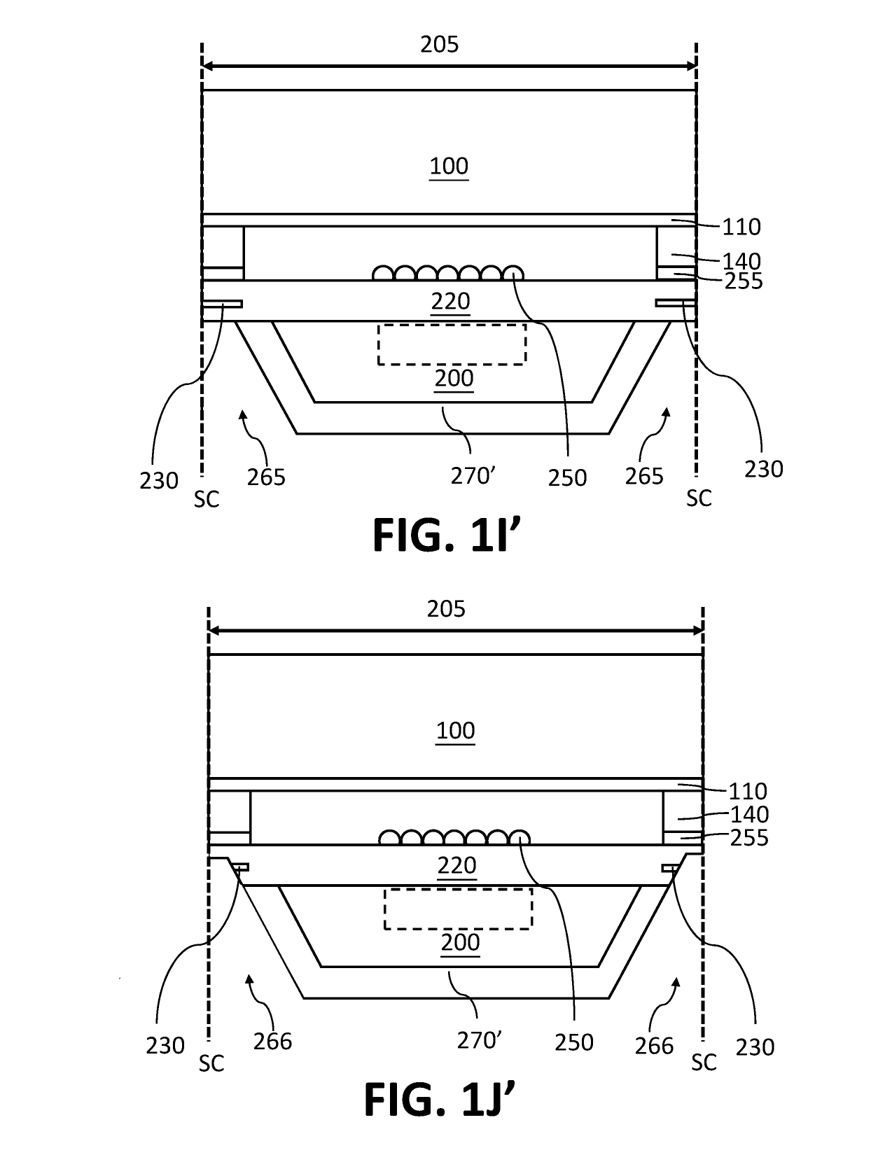

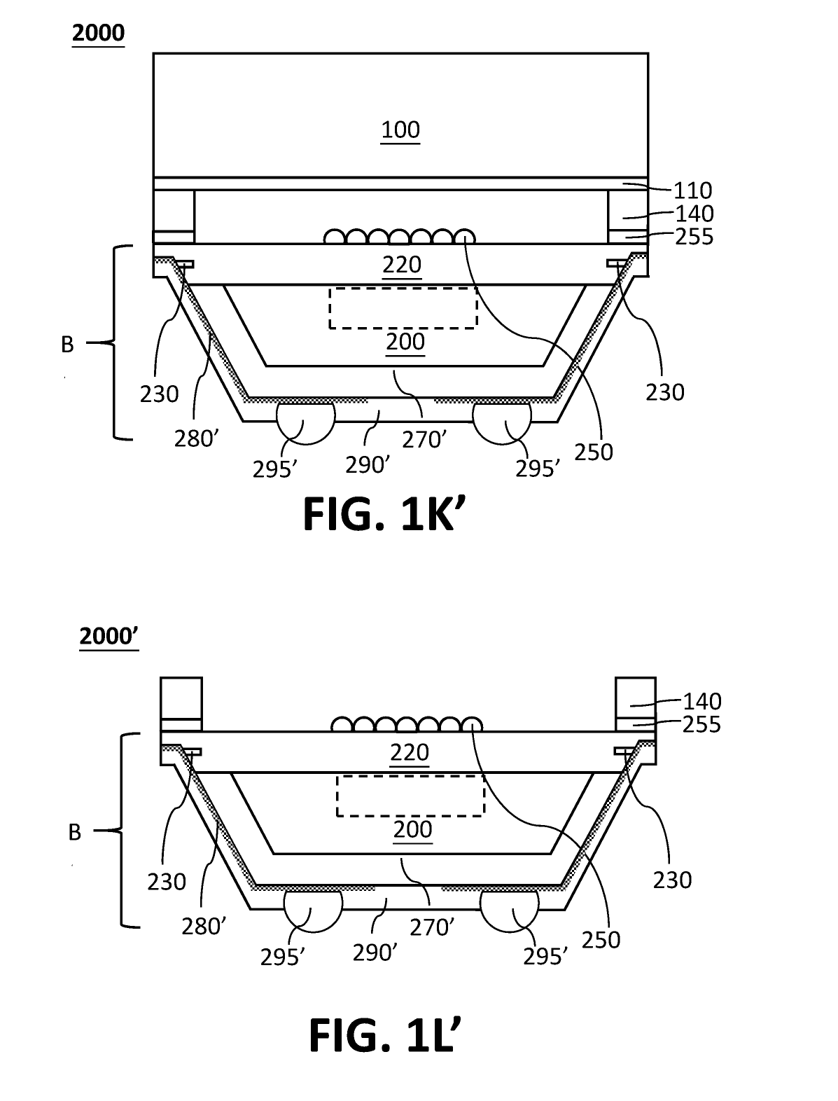

A detailed description of the chip scale sensing chip package and a method of manufacturing the same according to embodiment 1 of this invention is given below with reference to the accompany FIGS. 1A˜1K.

First, please refer to FIG. 1A. A cap layer 100 and a substrate 120 with the same thermal expansion coefficient (CTE) as that of the cap layer 100 are provided. Next, a first adhesive layer 110 is coated on the cap layer 100 to join the cap layer 100 and the substrate 120 to form a stacking layer 115. The cap layer 100 and the substrate 120 of this embodiment are consisted of glass materials with the same thermal expansion coefficient (CTE), and other materials such as acrylic, sapphire, quartz or silicon nitride with the same thermal expansion coefficient (CTE) can also be selected as the cap layer 100 and substrate 120 in other embodiments. According to other embodiments of this invention, the first adhesive layer 110 can also be coated on the substrate 120 to join the cap layer 100 to form a stacking layer 115 as illustrated in FIG. 1B.

Next, please refer to FIG. 1C. The substrate 120 of the stacking structure 115 is thinned by milling, grinding, polishing or etching to form a stacking structure 115′ with a substrate 120′ which is thinner than the substrate 120.

Next, please refer to FIG. 1D. A photoresist pattern 130 is formed on the substrate 120′ of the stacking structure 115′ by photolithography. The exposed substrate 120′ not masked by the photoresist pattern 130 is etched away to form a dam 140 as illustrated in FIG. 1E. A cap layer 100 having a dam 140 formed thereon is obtained after the photoresist pattern 130 is removed, wherein an adhesive 110 is sandwiched between the cap layer 100 and the dam 140. The thickness of the dam 140 can be adjusted between 20˜60 μm.

Next, please refer to FIG. 1G A sensing device substrate 200 having a first top surface 200a with a first insulating layer 220 formed thereon and a first bottom surface 200b opposite to each other is provided. The sensing device substrate 200 comprises a plurality of sensing device regions 205 spaced with each other by scribing channels (SC), and each sensing device region 205 comprises a sensing device 210 adjacent to the first top surface 205a and a plurality of conductive pads within the first insulating layer 220 adjacent to the sensing device 210. The sensing device substrate 200 of this embodiment is a silicon wafer with a plurality of sensing chip regions.

Next, please refer to FIG. 1H. The cap layer 100 with a dam 140 as illustrated in FIG. 1G is attaching to the sensing device substrate 200 by sandwiched a second adhesive 255 therebetween. The second adhesive layer 255 can also be pre-coated on the first insulating layer 220 or pre-coated on the dam 140.

Next, please refer to FIG H. The first bottom substrate 200b of the sensing device substrate 200 is processed by so-called TSV (through silicon via) processes. The first bottom substrate 200b of the sensing device substrate 200 is thinned by etching, milling, grinding or polishing to reduce its thickness. Then, a plurality of first through holes 260 exposing the conductive pads 230 are formed on the first bottom surface 200b. The cross-sectional area of each first through hole 260 decreases with the distance from the first bottom surface 200b in this embodiment. Then, a second insulating layer 270 is formed to overlay the thinned first bottom surface 200b, the first through holes and the exposed conductive pads 230. Then, part of the second insulating layer 270 on the bottom of each first through hole 260 is removed to form a plurality of second through holes (not shown) exposing the conductive pads 230. Next, a re-distribution layer 280 is formed on the second insulating layer 270 and electrically connected to each conductive pad 230 through each second through hole (not shown). The re-distribution layer 280 can be selected from one of the group consisted of aluminum, copper, gold, platinum, nickel, tin, or combination thereof, conductive polymers, conductive ceramics such as ITO or IZO, or other suitable conductive materials.

Next, please refer to FIG. 1J. A passivation layer 290 is formed to overlay the re-distribution layer 280. The passivation layer 290 has a plurality of third through holes (not shown) exposing the re-distribution layer 280, and a plurality of conductive structures 295 such as solder balls, solder bumps or conductive pillar are formed in the third through holes (not shown) by electroplating, screen printing or other suitable processes to electrically connect to the re-distribution layer 280. The passivation layer 290 of this embodiment can be selected from a material consisted of epoxy, inorganic material such as silicon oxide, silicon nitride, silicon oxynitride, metal oxide or combination thereof, organic polymer such as polyimide resin, benzocyclobutadiene, poly-p-xylene, naphthalene polymer, fluorocarbon compound, acrylate, solder mask or other suitable insulating materials. Finally, the sensing device substrate 200 is scribed along with the scribing channels (SC) to generate a plurality of chip scale sensing chip package 1000 as illustrated in FIG. 1J.

The cap layer 100 and the first adhesive layer 110 can also be peeled off before shipped to customers to generate a chip scale sensing chip package 1000′ as illustrated in FIG. 1K.

### Exemplary Embodiment 2

A detailed description of the chip scale sensing chip package and a method of manufacturing the same according to embodiment 2 of this invention is given below with reference to the accompany FIGS. 1I′˜1L′.

First, please refer to FIG. 1F. The structure as illustrated in FIG. 1H is processed by so-called T-contact processes. The first bottom substrate 200b of the sensing device substrate 200 is thinned by etching, milling, grinding or polishing to reduce its thickness. Then, a plurality of fourth through holes 265 corresponding to the conductive pads 230 and passing through the first top surface 200a and the first bottom surface 200b of the sensing device substrate 200 are formed, wherein the cross-sectional area of each first through hole 265 decreases with the distance from the first bottom surface 200b in this embodiment. Then, a second insulating layer 270′ is formed to overlay the thinned first bottom surface 200b and the fourth through holes 265.

Next, please refer to FIG. 1J′. Part of the second insulating layer 270′, part of the conductive pads 230 and part of the first insulating layer 220 under each of the fourth through hole 265 by notching to form a plurality of fifth through holes 266, wherein each fifth through hole 266 has a sidewall exposing the edge of one of the conductive pads 230.

Next, please refer to FIG. 1K′. A re-distribution layer 280′ is formed on the second insulating layer 270′ and the fifth through holes 266, wherein the re-distribution layer 280′ is electrically connected to each conductive pad 230 through each fifth through hole 266. The re-distribution layer 280′ can be selected from one of the group consisted of aluminum, copper, gold, platinum, nickel, tin, or combination thereof, conductive polymers, conductive ceramics such as ITO or IZO, or other suitable conductive materials. Next, a passivation layer 290′ is formed to overlay the re-distribution layer 280′. The passivation layer 290 has a plurality of sixth through holes (not shown) exposing the re-distribution layer 280, and a plurality of conductive structures 295′ such as solder balls, solder bumps or conductive pillar are formed in the third through holes (not shown) by electroplating, screen printing or other suitable processes to electrically connect to the re-distribution layer 280′. The passivation layer 290′ of this embodiment can be selected from a material consisted of epoxy, inorganic material such as silicon oxide, silicon nitride, silicon oxynitride, metal oxide or combination thereof, organic polymer such as polyimide resin, benzocyclobutadiene, poly-p-xylene, naphthalene polymer, fluorocarbon compound, acrylate, solder mask or other suitable insulating materials. Finally, the sensing device substrate 200 is scribed along with the scribing channels (SC) to generate a plurality of chip scale sensing chip package 2000 as illustrated in FIG. 1K′.

The cap layer 100 and the first adhesive layer 110 can also be peeled off before shipped to customers to generate a chip scale sensing chip package 2000′ as illustrated in FIG. 1L′.

As mentioned above, in order to provide an image sensing chip package with a better image quality, the sensing device of the image sensing chip package must be spaced with the cap layer by a proper distance to avoid ghost images or light reflection. This kind of image sensing chip package and a manufacturing method the same will be described in following embodiments 3 and 4.

### Exemplary Embodiment 3

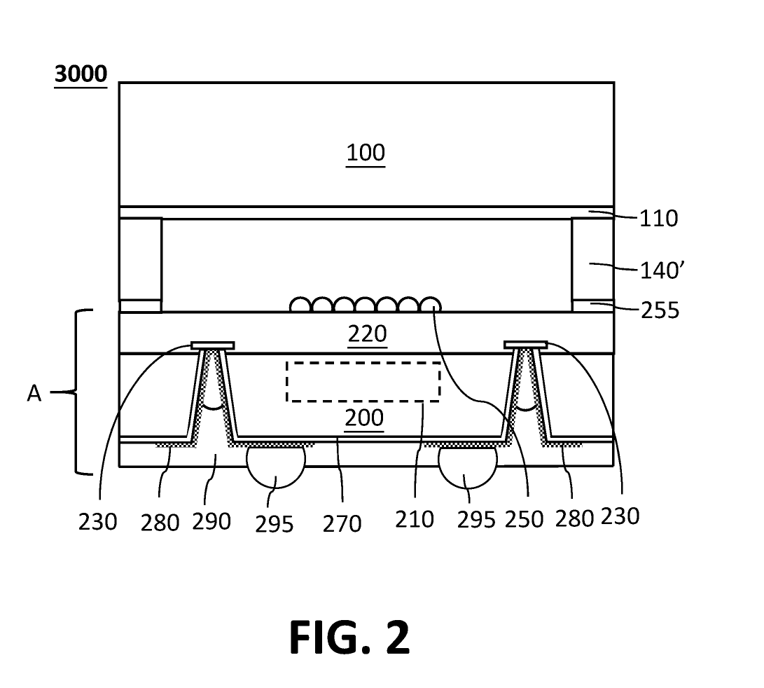

As illustrated in FIG. 2, the chip scale sensing chip package is manufactured by the same TSV processes as described in the embodiment 1 mentioned above. In order to maintain a proper distance between the sensing device 210 and the cap layer 100, the dam 140′ of this embodiment has a thickness of 400˜600 μm.

Accordingly, a chip scale sensing device package 300 which can avoid ghost images and light reflection as illustrated in FIG. 2 is generated. Besides, the dam 140′ and the cap layer 100 of this embodiment are consisted of glass materials with the same thermal expansion coefficients (CTE) to avoid bending, and other materials such as acrylic, sapphire, quartz or silicon nitride with the same thermal expansion coefficient (CTE) can also be selected as the cap layer 100 and substrate 120 in other embodiments.

### Exemplary Embodiment 4

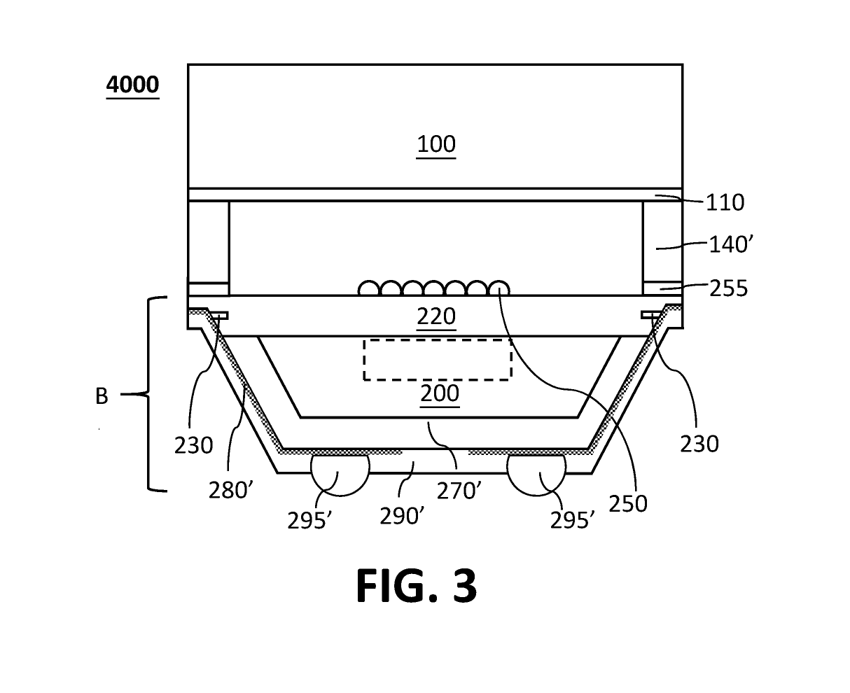

As illustrated in FIG. 3, the chip scale sensing chip package is manufactured by the same T-contact processes as described in the embodiment 2 mentioned above. In order to maintain a proper distance between the sensing device 210 and the cap layer 100, the dam 140′ of this embodiment has a thickness of 400˜600 μm.

Accordingly, a chip scale sensing device package 300 which can avoid ghost images and light reflection as illustrated in FIG. 3 is generated. Besides, the dam 140′ and the cap layer 100 of this embodiment are consisted of glass materials with the same thermal expansion coefficients (CTE) to avoid bending, and other materials such as acrylic, sapphire, quartz or silicon nitride with the same thermal expansion coefficient (CTE) can also be selected as the cap layer 100 and substrate 120 in other embodiments.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A chip scale sensing chip package, comprising:
a sensing chip, comprising:
a sensing device substrate having a first top surface and a first bottom surface opposite to each other;
a first insulating layer formed on the first top surface;
a sensing device formed within the sensing device substrate and adjacent to the first top surface; and
a plurality of conductive pads formed within the sensing device substrate and adjacent to the sensing device;
a wiring layer formed on the first bottom surface and connected to each of the conductive pads; and
a dam, formed on the first insulating layer adjacent to the sensing device.

2. The chip scale sensing chip package as claimed in claim 1, wherein the wiring layer comprises:
a plurality of first through holes passing through the first top surface and the first bottom surface of the sensing chip, and each of the first through holes has a bottom wall exposing one of the conductive pads and a sidewall surrounding the bottom wall;
a second insulating layer formed on the first bottom surface and overlaid the sidewall and the bottom wall of each first through hole;
a plurality of second through hole passing through the second insulating layer on each of the first through holes and exposing one of the conductive pads corresponding thereof;
a re-distribution layer formed on the second insulating layer and electrically connected to each of the conductive pads via each of the second through holes;
a passivation layer formed on the re-distribution layer and having a plurality of third through holes exposing the re-distribution layer; and
a plurality conductive structures respectively formed in each of the third through holes to respectively interconnected to re-distribution layer.

3. The chip scale sensing chip package as claimed in claim 1, wherein the wiring layer comprises:
a plurality of fifth through holes passing through the first top surface and the first bottom surface of the sensing chip, wherein each fifth through hole has a sidewall exposing the edge of each conductive pad;
a second insulating layer formed on the first bottom surface and overlaid the sidewall of each fifth through hole;
a re-distribution layer formed on the second insulating layer and electrically connected to the edge of each conductive pad;
a passivation layer formed on the re-distribution layer and having a plurality of sixth through holes exposing the re-distribution layer; and
a plurality conductive structures respectively formed in each of the sixth through holes to respectively interconnected to re-distribution layer.

4. The chip scale sensing chip package as claimed in claim 2, further comprising a cap layer formed above the sensing device and joined with the dam.

5. The chip scale sensing chip package as claimed in claim 4, the dam and the cap layer are consisted of materials with the same thermal expansion coefficients.

6. The chip scale sensing chip package as claimed in claim 5, further comprising a first adhesive layer sandwiched between the cap layer and the dam.

7. The chip scale sensing chip package as claimed in claim 6, further comprising a second adhesive layer sandwiched between the dam and the first insulating layer.

8. The chip scale sensing chip package as claimed in claim 4, wherein the dam has a thickness of 20˜60 μm.

9. The chip scale sensing chip package as claimed in claim 4, wherein the dam has a thickness of 400˜600 μm.

10. A method of manufacturing a chip scale sensing chip package, comprising the steps of:
providing a sensing device substrate having a first top surface with a first insulating layer formed thereon and a first bottom surface, wherein the sensing device substrate has a plurality of sensing chip regions spaced by a plurality of scribing channels, and each sensing chip comprises a sensing device formed in the sensing device substrate adjacent to the first top surface and a plurality of conductive pads formed within the sensing device substrate and adjacent to the sensing device;
providing a cap layer having a second top surface with a plurality of dams formed thereon and a second bottom surface opposite to each other, wherein each dam corresponds to each sensing chip region, and the cap layer and the dam have the same thermal expansion coefficients;
attaching the cap layer to the first top surface of the sensing device substrate to sandwich the dam between the cap layer and the sensing device substrate;
forming a wiring layer on the first bottom surface to respectively interconnect each of the conductive pads;
forming a passivation layer on the wiring layer; and
scribing the sensing device substrate along the scribing channels to generate a plurality of chip scale sensing chip packages.

11. The method of manufacturing a chip scale sensing chip package as claimed in claim 10, the sensing device substrate, the dam and the cap layer are consisted of materials with the same thermal expansion coefficients.

12. The method of manufacturing a chip scale sensing chip package as claimed in claim 10, wherein the method of manufacturing the dam comprises the steps of:
providing a substrate;
formed a first adhesive layer on the substrate or on the cap layer;
joining the substrate and the cap layer to form a stacking layer by sandwiching the first adhesive layer therebetween;
patterning the substrate to form dams on the cap layer, wherein the first adhesive layer is sandwiched between the dam and the substrate.

13. The method of manufacturing a chip scale sensing chip package as claimed in claim 10, further comprising a step of peeling off the cap layer from each of the chip scale sensing chip package.

14. The method of manufacturing a chip scale sensing chip package as claimed in claim 10, whereby the method of manufacturing the wiring layer comprises the steps of:
thinning the first bottom surface of the sensing device substrate;
forming a plurality of first through holes on the thinned first bottom surface, wherein each of the first through holes exposes one of the conductive pads;
forming a second insulating layer overlaid the thinned first bottom surface, the first through holes and the exposed conductive pads;
removing part of the second insulating layer on the bottom of each first through hole to form a plurality of second through holes exposing the conductive pads;
forming a re-distribution layer on the second insulating layer and electrically connecting to each conductive pad through each second through hole;
forming a passivation layer on the re-distribution layer, whereby the passivation layer has a plurality of third through holes exposing the re-distribution layer; and
forming a conductive structure in each of the third through holes and electrically connecting to the re-distribution layer.

15. The method of manufacturing a chip scale sensing chip package as claimed in claim 14, wherein the cross-sectional area of each first through hole decreases with the distance from the first bottom surface.

16. The method of manufacturing a chip scale sensing chip package as claimed in claim 10, whereby the method of manufacturing the wiring layer comprises the steps of:
thinning the first bottom surface of the sensing device substrate;
forming a plurality of fourth through holes on the thinned first bottom surface, wherein each of the fourth through holes exposes one of the conductive pads;
forming a second insulating layer overlaid the thinned first bottom surface, the fourth through holes and the exposed conductive pads;
removing part of the second insulating layer, part of the conductive pads and part of the first insulating layer under each of the fourth through hole by notching to form a plurality of fifth through holes, wherein each fifth through hole has a sidewall exposing the edge of one of the conductive pads;
forming a re-distribution layer on the second insulating layer and electrically connecting to each conductive pad through each fifth through hole;
forming a passivation layer on the re-distribution layer, whereby the passivation layer has a plurality of sixth through holes exposing the re-distribution layer; and
forming a conductive structure in each of the sixth through holes and electrically connecting to the re-distribution layer.

17. The method of manufacturing a chip scale sensing chip package as claimed in claim 16, wherein the cross-sectional area of each fourth through hole decreases with the distance from the first bottom surface.

18. The method of manufacturing a chip scale sensing chip package as claimed in claim 10, further comprising a second adhesive layer sandwiched between the dam and the first insulating layer.

19. The method of manufacturing a chip scale sensing chip package as claimed in claim 10, wherein the dam has a thickness of 20˜60 μm.

20. The method of manufacturing a chip scale sensing chip package as claimed in claim 10, wherein the dam has a thickness of 400∞600 μm.
